(19) United States
(12) Patent Application Publication
(10) Pub. No.: US 2011/0272015 A1
(43) Pub. Date: Nov. 10, 2011

(54) THIN FILM SOLAR CELL AND METHOD FOR MANUFACTURING THE SAME

(76) Inventors: Soohyun KIM, Seoul (KR); Byungkee Lee, Seoul (KR); Wooyoung Kim, Seoul (KR); Sehwon Ahn, Seoul (KR); Hongcheol Lee, Seoul (KR)

(21) Appl. No.: 13/185,045

(22) Filed: Jul. 18, 2011

(30) Foreign Application Priority Data
Dec. 16, 2010 (KR) 10-2010-0128996

(51) Int. Cl. H01L 31/06; H01L 31/18

(52) U.S. Cl. 136/255; 438/57; 257/E31.001

(57) ABSTRACT

A thin film solar cell and a method for manufacturing the same are discussed. The thin film solar cell includes a substrate, a first electrode and a second electrode positioned on the substrate, and a first photoelectric conversion unit positioned between the first electrode and the second electrode. The first photoelectric conversion unit includes an intrinsic layer for light absorption containing microcrystalline silicon germanium, a p-type doped layer and an n-type doped layer respectively positioned on and under the intrinsic layer, and a seed layer not containing germanium positioned between the p-type doped layer and the intrinsic layer.

This application claims priority to and the benefit of Korean Patent Application No. 10-2010-0128996 filed in the Korean Intellectual Property Office on Dec. 16, 2010, the entire contents of which are incorporated herein by reference.

### BACKGROUND OF THE INVENTION

1. Field of the Invention

Embodiments of the invention relate to a thin film solar cell including a seed layer and a method for manufacturing the same.

2. Description of the Related Art

Solar cells use an infinite energy source, i.e., the sun as an energy source, scarcely produce pollution materials in an electricity generation process, and have a very long life span equal to or longer than 20 years. Furthermore, the solar cells have been particularly spotlighted because of a large ripple effect on the economy via the solar related industries. Thus, many countries have fostered solar cells as a next generation industry.

Most of the solar cells have been manufactured based on a single crystal silicon wafer or a polycrystalline silicon wafer. In addition, thin film solar cells using silicon have been manufactured in lesser quantities.

The solar cells have the problem of a very high electricity generation cost compared to other energy sources. Thus, the electricity generation cost of the solar cells has to be greatly reduced so as to meet future demands for clean energy.

However, because a bulk solar cell manufactured based on the single crystal silicon wafer or the polycrystalline silicon wafer now uses a raw material having a thickness of at least 150 μm, the cost of the raw material, i.e., silicon, makes up most of the production cost of the bulk solar cell. Further, because the supply of the raw material does not meet the rapidly increasing demand, it is difficult to reduce the production cost of the bulk solar cell.

On the other hand, because a thickness of the thin film solar cell is less than 2 μm, an amount of raw material used in the thin film solar cell is much less than an amount of raw material used in the bulk solar cell. Thus, the thin film solar cell is more advantageous than the bulk solar cell in terms of the electricity generation cost, i.e., the production cost. However, an electricity generation performance of the thin film solar cell is one half of an electricity generation performance of the bulk solar cell based on a given area.

The efficiency of the solar cell is generally expressed by a magnitude of electric power obtained at a light intensity of 100 mW/cm² in terms of percentage. The efficiency of the bulk solar cell is approximately 12% to 20%, and the efficiency of the thin film solar cell is approximately 8% to 9%. In other words, the efficiency of the bulk solar cell is greater than the efficiency of the thin film solar cell. Accordingly, much stepped up effort to increase the efficiency of the thin film solar cell is being made.

The most basic structure of the thin film solar cell is a single junction structure. A single junction thin film solar cell has a structure in which a photoelectric conversion unit is positioned between a front electrode and a back electrode and includes an intrinsic layer for light absorption, a p-type doped layer, and an n-type doped layer. The p-type doped layer and the n-type doped layer are respectively formed on and under the intrinsic layer, thereby forming an inner electric field for separating carriers produced by solar light.

However, the efficiency of the single junction thin film solar cell is not high. Thus, a double junction thin film solar cell including two photoelectric conversion units between a front electrode and a back electrode and a triple junction thin film solar cell including three photoelectric conversion units between a front electrode and a back electrode have been developed, so as to increase the efficiency of the thin film solar cell.

Each of the double junction thin film solar cell and the triple junction thin film solar cell has the configuration in which a first photoelectric conversion unit first absorbing solar light (for example, one positioned closer to the front electrode than the back electrode) is formed of a semiconductor material (for example, amorphous silicon) having a wide optical band gap, and a second or third photoelectric conversion unit later absorbing the solar light (for example, one positioned closer to the back electrode than the front electrode) is formed of a semiconductor material (for example, microcrystalline silicon germanium) having a narrow optical band gap. Hence, the first photoelectric conversion unit mostly absorbs solar light of a short wavelength band, and the second or third photoelectric conversion unit mostly absorbs solar light of a long wavelength band. As a result, the efficiency of each of the double junction thin film solar cell and the triple junction thin film solar cell is greater than the efficiency of the single junction thin film solar cell.

### SUMMARY OF THE INVENTION

In one aspect, there is a thin film solar cell including a substrate, a first electrode and a second electrode positioned on the substrate, and a first photoelectric conversion unit positioned between the first electrode and the second electrode, the first photoelectric conversion unit including an intrinsic layer for light absorption containing microcrystalline silicon germanium, a p-type doped layer and an n-type doped layer respectively positioned on and under the intrinsic layer, and a seed layer not containing germanium positioned between the p-type doped layer and the intrinsic layer.

The seed layer may be formed of a combination of silicon and hydrogen. The seed layer may have a thickness of about 10 nm to 100 nm.

A concentration of germanium contained in the intrinsic layer may be equal to or less than 40 atom %. The intrinsic layer may include a first region having a non-uniform concentration of germanium and a second region having a uniform concentration of germanium.

The first region of the intrinsic layer may contact the seed layer, and the second region of the intrinsic layer may contact the n-type doped layer. A concentration of germanium in the first region may gradually increase as it goes from a location close to the seed layer to the second region.

The thin film solar cell may further include at least one second photoelectric conversion unit positioned between the first electrode and the first photoelectric conversion unit or the first photoelectric conversion unit and the second electrode. The first photoelectric conversion unit may be configured as a lower cell.

In another aspect, there is a method of manufacturing a thin film solar cell including a seed layer between a doped layer and an intrinsic layer, the method including forming the seed layer using a first process gas containing silicon and hydrogen, and forming the intrinsic layer on the seed layer using the first process gas and a second process gas containing silicon, hydrogen, and germanium.

The forming of the seed layer may include gradually reducing a concentration of the first process gas to a first setting concentration up to a first setting time.

The forming of the intrinsic layer may include gradually increasing a concentration of the second process gas to a second setting concentration from the first setting time to a second setting time. The forming of the intrinsic layer may include, after the second setting time has passed, uniformly keeping the concentration of the second process gas at the second setting concentration up to a third setting time. The forming of the intrinsic layer may include uniformly keeping the concentration of the first process gas at the first setting concentration from the second setting time to the third setting time.

The first setting concentration of the first process gas may be lower than the second setting concentration of the second process gas. The concentration of the second process gas may gradually increase and then exceed the first setting concentration of the first process gas between the first setting time and the second setting time.

According to the above-described configuration, the seed layer not containing germanium is positioned on the p-type doped layer, and the intrinsic layer containing microcrystalline silicon germanium is positioned on the seed layer. Accordingly, an incubation layer is prevented from being formed, a microcrystalline growth is normally implemented, and a recombination of carriers is prevented or reduced. Hence, a life span of the thin film solar cell increases.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a graph illustrating a correlation between an incubation layer and a germanium concentration in a thin film solar cell containing microcrystalline silicon germanium;

FIG. 2 is a graph illustrating a flow rate of a gas used to manufacture an intrinsic layer over time in a thin film solar cell not including a seed layer;

FIG. 3 is a graph illustrating a flow rate of a gas used to manufacture a seed layer containing germanium and an intrinsic layer over time;

FIG. 4 is a partial cross-sectional view schematically illustrating a double junction thin film solar cell according to a first example embodiment of the invention;

FIG. 5 is a partial cross-sectional view schematically illustrating a triple junction thin film solar cell according to a second example embodiment of the invention; and

FIG. 6 is a graph illustrating a flow rate of a gas used to manufacture a thin film solar cell according to an example embodiment of the invention over time.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

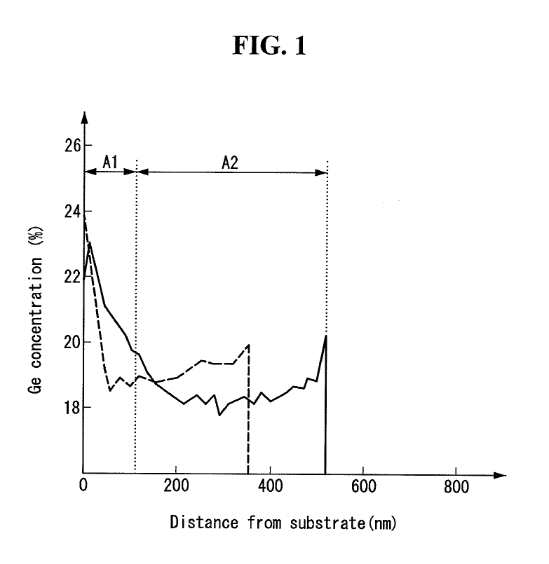

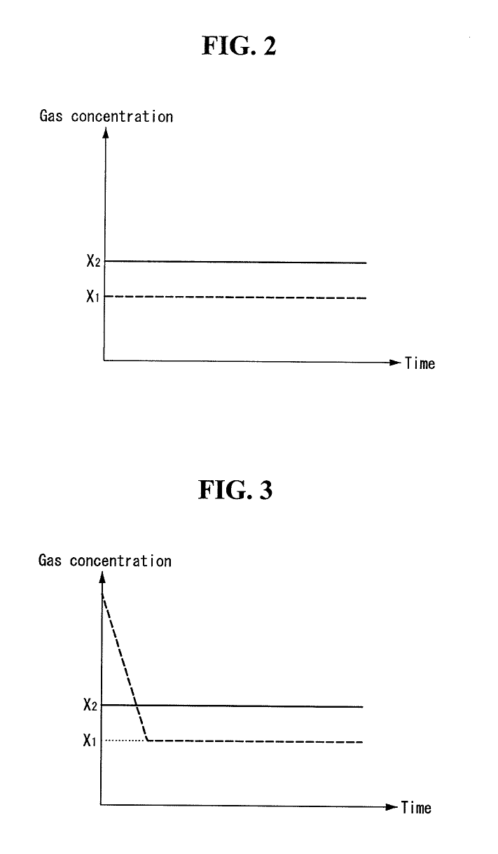

FIG. 1 is a graph illustrating a correlation between an incubation layer and a germanium concentration in a thin film solar cell containing microcrystalline silicon germanium. FIG. 2 is a graph illustrating a flow rate of a gas used to manufacture an intrinsic layer over time in a thin film solar cell not including a seed layer. FIG. 3 is a graph illustrating a flow rate of a gas used to manufacture a seed layer containing germanium and an intrinsic layer over time.

Efficiency of a thin film solar cell is greatly affected by characteristics of an interface between a p-typed doped layer and an intrinsic layer. This is described in detail below with reference to FIGS. 1 to 3.

As shown in FIG. 2, an intrinsic layer is formed using microcrystalline silicon germanium by supplying a first process gas (H₂/SiH₄) containing silicon (Si) and hydrogen (H) while uniformly keeping a concentration of the first process gas at a first setting concentration X1 and supplying a second process gas (GeH₄/SiH₄) containing silicon (Si), hydrogen (H), and germanium (Ge) while uniformly keeping a concentration of the second process gas at a second setting concentration X2.

In this instance, before the microcrystalline growth is normally implemented, an incubation layer is formed. Further, as shown in FIG. 1, a Ge concentration of the incubation layer in a formation period A1 of the incubation layer increases to about 5-15% as compared to a normal crystallization period A2.

FIG. 1 is the graph illustrating an abnormal increase of the Ge concentration in an initial incubation layer region of a crystal growth confirmed by a SIMS depth profile. In FIG. 1, the dotted line indicates the Ge concentration obtained when (GeH₄+SiH₄)/H₂ is about 1.0%, and the solid line indicates the Ge concentration obtained when (GeH₄+SiH₄)/H₂ is about 2.0%. Further, a transverse axis indicates a distance from a substrate, and a longitudinal axis indicates the concentration of germanium (Ge).

Because germanium (Ge) existing in the incubation layer serves as a defect that hinders the movement of carriers, characteristics of the thin film solar cell are reduced. Accordingly, a method using a seed layer for preventing the incubation layer from being formed has been developed.

More specifically, during the formation of the seed layer, the first process gas is supplied while gradually reducing the concentration of the first process gas until the concentration of the first process gas reaches the first setting concentration X1, and the second process gas is supplied while uniformly keeping the concentration of the second process gas at the second setting concentration X2.

After the seed layer is formed, the intrinsic layer is formed by supplying the first process gas while uniformly keeping the concentration of the first process gas at the first setting concentration X1 and supplying the second process gas while uniformly keeping the concentration of the second process gas at the second setting concentration X2.

However, in the above-described method, because both the first process gas and the second process gas containing germanium are supplied to form the seed layer, the microcrystalline transition is reduced. Therefore, it is difficult to completely remove the incubation layer, and it is difficult to uniformly control the Ge concentration.

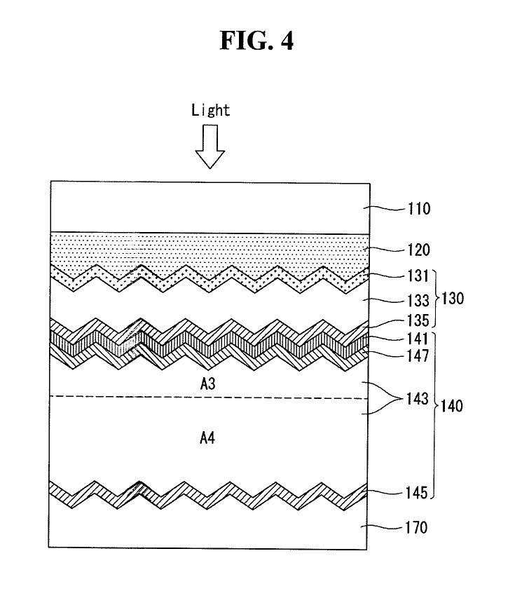

Hereinafter, example embodiments of the invention describe a thin film solar cell capable of solving the above-described problems with reference to FIGS. 4 to 7.

FIG. 4 schematically illustrates a thin film solar cell according to a first example embodiment of the invention. More specifically, FIG. 4 is a partial cross-sectional view of a double junction thin film solar cell according to the first example embodiment of the invention.

As shown in FIG. 4, a double junction thin film solar cell according to the first example embodiment of the invention has a superstrate structure in which light is incident through a substrate 110.

More specifically, the double junction thin film solar cell includes a substrate 110 formed of, for example, glass or transparent plastic, etc., a first electrode 120 positioned on the substrate 110, a first photoelectric conversion unit 130 positioned on the first electrode 120, a second photoelectric conversion unit 140 positioned on the first photoelectric conversion unit 130, and a back reflection layer 170 positioned on the second photoelectric conversion unit 140.

The back reflection layer 170 may generally serve as a second electrode. Alternatively, the back reflection layer 170 and a separate second electrode may be configured as distinct layers.

The first electrode 120 is entirely formed on one surface of the substrate 110 and is electrically connected to the first photoelectric conversion unit 130. Thus, the first electrode 120 collects carriers (for example, holes) produced by light and outputs the carriers. Further, the first electrode 120 may serve as an anti-reflection layer.

The first electrode 120 has a light scattering surface that scatters light reflected from the back reflection layer 170 to thereby increase a light absorptance. The light scattering surface of the first electrode 120 may be formed by forming a plurality of uneven portions on one surface of the first electrode 120, for example, the surface of the first electrode 120 adjoining the first photoelectric conversion unit 130.

For example, the light scattering surface of the first electrode 120 may be formed by forming a transparent conductive oxide (TCO) layer through a sputtering method and then wet etching the surface of the TCO layer to thereby form the plurality of uneven portions. Alternatively, the light scattering surface of the first electrode 120 may be formed by forming the TCO layer using a low pressure chemical vapor deposition (LPCVD) method. The LPCVD method may cause the plurality of uneven portions to be automatically formed on the surface of the first electrode 120 because of characteristics of a deposition equipment and/or a deposition method. Thus, a separate etching process for forming the light scattering surface is not necessary.

The plurality of uneven portions of the light scattering surface has different widths, different heights, different shapes, etc. On the other hand, the plurality of uneven portions of the light scattering surface have a height of about 1 μm to 10 μm.

As discussed above, when the first electrode 120 has the light scattering surface, light reflected from the back reflection layer 170 is scattered from the light scattering surface. Hence, the light absorptance of the first photoelectric conversion unit 130 increases.

The first electrode 120 requires high light transmittance and high electrical conductivity, so as to transmit most of light incident on the substrate 110 and smoothly pass through electric current. For this, the first electrode 120 may be formed of transparent conductive oxide (TCO). For example, the first electrode 120 may be formed of at least one selected from the group consisting of indium tin oxide (ITO), tin-based oxide (for example, SnO₂), AgO, ZnO—Ga₂O₃ (or ZnO—Al₂O₃), fluorine tin oxide (FTO), and a combination thereof. A specific resistance of the first electrode 120 may be approximately 10⁻² Ω·cm to 10⁻¹¹ Ω·cm.

The first photoelectric conversion unit 130 may be formed of hydrogenated amorphous silicon (a-Si:H). The first photoelectric conversion unit 130 has an optical band gap of about 1.7 eV and mostly absorbs light of a short wavelength band such as near ultraviolet light, purple light, and/or blue light.

The first photoelectric conversion unit 130 includes a semiconductor layer 131 (for example, a first p-type doped layer) of a first conductive type, a first intrinsic layer 133, and a semiconductor layer 135 (for example, a first n-type doped layer) of a second conductive type opposite the first conductive type, that are sequentially stacked on the first electrode 120.

The first p-type doped layer 131 may be formed by mixing a gas containing impurities of a group III element such as boron (B), gallium (Ga), and indium (In) with a process gas containing silicon (Si). In the embodiment of the invention, the first p-type doped layer 131 may be formed of hydrogenated amorphous silicon (a-Si:H) or using other materials.

The first intrinsic layer 133 prevents or reduces a recombination of carriers and absorbs the incident light. The carriers, i.e., electrons and holes are mostly produced in the first intrinsic layer 133. The first intrinsic layer 133 may be formed of hydrogenated amorphous silicon (a-Si:H) or using other materials. The first intrinsic layer 133 may have a thickness of about 200 nm to 300 nm.

The first n-type doped layer 135 may be formed by mixing a gas containing impurities of a group V element such as phosphorus (P), arsenic (As), and antimony (Sb) with a process gas containing silicon (Si).

The first photoelectric conversion unit 130 may be formed using a chemical vapor deposition (CVD) method such as a plasma enhanced CVD (PECVD) method.

The first p-type doped layer 131 and the first n-type doped layer 135 of the first photoelectric conversion unit 130 form a p-n junction with the first intrinsic layer 133 interposed therebetween. Hence, electrons and holes produced in the first intrinsic layer 133 are separated from each other by a contact potential difference resulting from a photovoltaic effect and move in different directions.

The second photoelectric conversion unit 140 positioned on the first photoelectric conversion unit 130 is a cell formed to include microcrystalline silicon (μc-Si). The second photoelectric conversion unit 140 includes a second p-type doped layer 141, a second intrinsic layer 143, and a second n-type doped layer 145, that are sequentially formed on the first n-type doped layer 135 of the first photoelectric conversion unit 130.

The second intrinsic layer 143 formed of microcrystalline silicon germanium (μc-SiGe) may have a thickness of about 1,500 nm to 2,000 nm. The thickness of the second intrinsic layer 143 may greater than the thickness of the first intrinsic layer 133, so as to sufficiently absorb light of a long wavelength band.

The second p-type doped layer 141 and the second n-type doped layer 145 may be formed using the same material as the second intrinsic layer 143.

The second photoelectric conversion unit 140 further includes a seed layer 147 between the second p-type doped layer 141 and the second intrinsic layer 143.

The seed layer 147 is formed so as to prevent or reduce a formation of an incubation layer. In the embodiment of the invention, the seed layer 147 does not contain germanium. In other words, the seed layer 147 is formed of a combination of silicon (Si) and hydrogen (H) and has a thickness of about 10 nm to 100 nm.

Because the seed layer 147 does not contain germanium, the seed layer 147 has an optical band gap of about 1.1 eV. On the other hand, the second intrinsic layer 143 containing germanium has an optical band gap of about 0.9 eV to 1.0 eV.

Accordingly, when the second photoelectric conversion unit 140 includes the seed layer 147 not containing germanium, the discontinuity of a wavelength band is generated in the second photoelectric conversion unit 140. Hence, the seed layer 147 affects the movement of carriers in the second photoelectric conversion unit 140.

The second intrinsic layer 143 includes a first region A3 having a non-uniform concentration of germanium and a second region A4 having a uniform concentration of germanium, so that carriers smoothly move in the second photoelectric conversion unit 140.

The first region A3 contacts the seed layer 147, and the second region A4 contacts the second n-type doped layer 145. The Ge concentration in the first region A3 gradually increases as it goes from a location close to the seed layer 147 to the second region A4.

As discussed above, when the second intrinsic layer 143 includes the two first and second regions A3 and A4, the discontinuity of the wavelength band may be prevented.

The Ge concentration of the second intrinsic layer 143 may be equal to or less than 40 atom %.

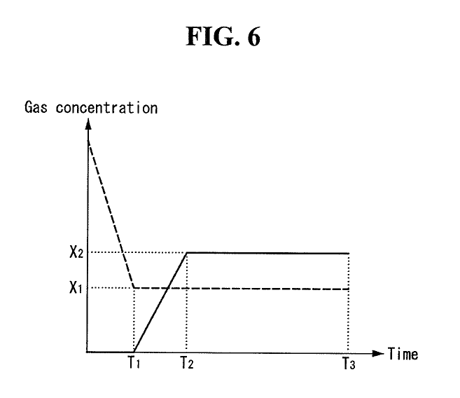

A method of manufacturing the thin film solar cell according to the example embodiment of the invention is described below with reference to FIG. 6.

A first electrode 120 and a first photoelectric conversion unit 130 are formed on a substrate 110, and then a second photoelectric conversion unit 140 is formed on the first photoelectric conversion unit 130.

Particularly, a second p-type doped layer 141 of the second photoelectric conversion unit 140 is formed on a first n-type doped layer 135 of the first photoelectric conversion unit 130.

After the second p-type doped layer 141 is formed, a first process gas (H₂/SiH₄) and a second process gas (GeH₄/SiH₄) are supplied based on a gas flow rate shown in FIG. 6 to sequentially form a seed layer 147 and a second intrinsic layer 143 of the second photoelectric conversion unit 140. In other words, only the first process gas (H₂/SiH₄) is supplied during the formation of the seed layer 147, and both the first process gas (H₂/SiH₄) and the second process gas (GeH₄/SiH₄) are supplied during the formation of the second intrinsic layer 143.

More specifically, as shown in FIG. 6, for a first setting time T1 when the seed layer 147 is formed, the first process gas is supplied while gradually reducing a concentration of the first process gas to a first setting concentration X1, and the second process gas is not supplied. In this instance, the first setting time T1 may be expressed by (or correspond to) a thickness of the seed layer 147, which will be formed.

After the seed layer 147 is formed as discussed above, a first region A3 of the second intrinsic layer 143 is formed.

For a second setting time T2 when the first region A3 of the second intrinsic layer 143 is formed, the second process gas is supplied while gradually increasing a concentration of the second process gas to a second setting concentration X2, and the first process gas is constantly supplied by keeping the concentration of the first process gas at the first setting concentration X1.

The second setting concentration X2 of the second process gas is set to be higher than the first setting concentration X1 of the first process gas. Thus, the concentration of the second process gas gradually increases and then exceeds the first setting concentration X1 of the first process gas between the first setting time and the second setting time T2.

After the first region A3 of the second intrinsic layer 143 is formed, and up to a third setting time T3 when the second region A4 of the second intrinsic layer 143 is formed, the first process gas is uniformly supplied by keeping the concentration of the first process gas at the first setting concentration X1, and the second process gas is uniformly supplied by keeping the concentration of the second process gas at the second setting concentration X2.

After the second intrinsic layer 143 including the first and second regions A3 and A4 is formed, a second n-type doped layer 145 is formed on the second intrinsic layer 143. A back reflection layer 170 is then formed on the second n-type doped layer 145, thereby completing the thin film solar cell.

A middle reflection layer may be formed between the first photoelectric conversion unit 130 and the second photoelectric conversion unit 140. The middle reflection layer may reflect light of a short wavelength band toward the first photoelectric conversion unit 130 and transmit light of a long wavelength band toward the second photoelectric conversion unit 140.

So far, the embodiment of the invention has described the double junction thin film solar cell. The embodiment of the invention may include a triple junction thin film solar cell.

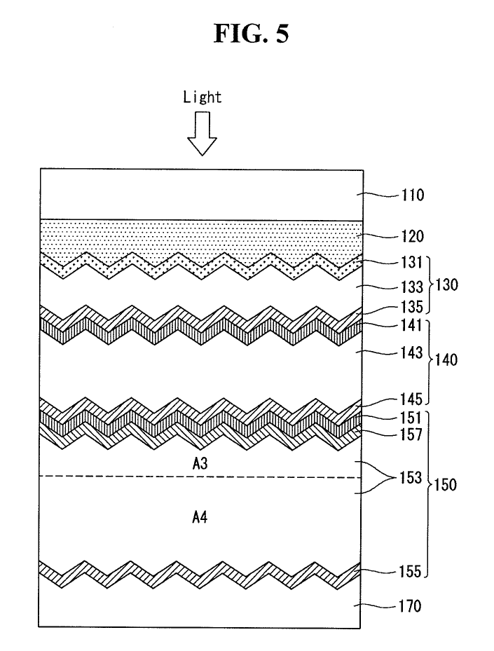

FIG. 5 schematically illustrates a thin film solar cell according to a second example embodiment of the invention. More specifically, FIG. 5 is a partial cross-sectional view of a triple junction thin film solar cell according to the second example embodiment of the invention. In the following explanations, structural elements having the same functions and structures as those discussed previously are designated by the same reference numerals, and the explanations therefore will not be repeated unless they are necessary.

The triple junction thin film solar cell according to the second example embodiment of the invention includes a first photoelectric conversion unit 130, a second photoelectric conversion unit 140, and a third photoelectric conversion unit 150 that are sequentially positioned between a first electrode 120 and a back reflection layer 170.

In the triple junction thin film solar cell, the third photoelectric conversion unit 150 may be formed of microcrystalline silicon germanium.

In the first example embodiment of the invention illustrated in FIG. 4, the second photoelectric conversion unit 140 includes the seed layer 147 not containing germanium. On the other hand, in the second example embodiment of the invention illustrated in FIG. 5, the third photoelectric conversion unit 150 includes a seed layer 157 not containing germanium.

More specifically, a third p-type doped layer 151, the seed layer 157, a third intrinsic layer 153, and a third n-type doped layer 155 are sequentially positioned on a second n-type doped layer 145 of the second photoelectric conversion unit 140. The seed layer 157 and the third intrinsic layer 153 have the same configuration as the seed layer 147 and the second intrinsic layer 143 described in the first example embodiment of the invention, respectively.

In embodiments of the invention, a seed layer not containing germanium (Ge) also includes a layer being essentially free of germanium (Ge). Accordingly, the seed layer may be completely free of germanium (Ge), or may simply include very minute amounts of unintentionally included germanium (Ge) or very minute amounts of germanium (Ge) that cannot be eliminated during processing. In embodiments of the invention, the one or more photoelectric conversion units of the thin film solar cell may be formed of any semiconductor material. Accordingly, materials for the one or more photoelectric conversion units may include Cadmium telluride (CdTe), Copper indium gallium selenide (CIGS) and/or other materials, including other thin film solar cell materials.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A thin film solar cell comprising:
a substrate;
a first electrode and a second electrode positioned on the substrate; and
a first photoelectric conversion unit positioned between the first electrode and the second electrode, the first photoelectric conversion unit including an intrinsic layer for light absorption containing microcrystalline silicon germanium, a p-type doped layer and an n-type doped layer respectively positioned on and under the intrinsic layer, and a seed layer not containing germanium positioned between the p-type doped layer and the intrinsic layer.

2. The thin film solar cell of claim 1, wherein the seed layer is formed of a combination of silicon and hydrogen.

3. The thin film solar cell of claim 1, wherein the seed layer has a thickness of about 10 nm to 100 nm.

4. The thin film solar cell of claim 1, wherein a concentration of germanium contained in the intrinsic layer is equal to or less than 40 atom %.

5. The thin film solar cell of claim 4, wherein the intrinsic layer includes a first region having a non-uniform concentration of germanium.

6. The thin film solar cell of claim 5, wherein the first region of the intrinsic layer contacts the seed layer.

7. The thin film solar cell of claim 6, wherein the intrinsic layer further includes a second region having a uniform concentration of germanium.

8. The thin film solar cell of claim 7, wherein the second region of the intrinsic layer contacts the n-type doped layer.

9. The thin film solar cell of claim 8, wherein a concentration of germanium in the first region gradually increases going from a location close to the seed layer to the second region.

10. The thin film solar cell of claim 1, further comprising at least one second photoelectric conversion unit positioned between the first electrode and the first photoelectric conversion unit or the first photoelectric conversion unit and the second electrode,
wherein the first photoelectric conversion unit is configured as a lower cell.

11. A method for manufacturing a thin film solar cell including a seed layer between a doped layer and an intrinsic layer, the method comprising:
forming the seed layer using a first process gas containing silicon and hydrogen; and
forming the intrinsic layer on the seed layer using the first process gas and a second process gas containing silicon, hydrogen, and germanium.

12. The method of claim 11, wherein the forming of the seed layer includes gradually reducing a concentration of the first process gas to a first setting concentration up to a first setting time.

13. The method of claim 11, wherein the forming of the intrinsic layer includes gradually increasing a concentration of the second process gas to a second setting concentration from the first setting time to a second setting time.

14. The method of claim 13, wherein the forming of the intrinsic layer includes, after the second setting time has passed, uniformly keeping the concentration of the second process gas at the second setting concentration up to a third setting time.

15. The method of claim 14, wherein the forming of the intrinsic layer includes uniformly keeping a concentration of the first process gas at a first setting concentration from the second setting time to the third setting time.

16. The method of claim 15, wherein the first setting concentration of the first process gas is lower than the second setting concentration of the second process gas.

17. The method of claim 16, wherein the concentration of the second process gas gradually increases and then exceeds the first setting concentration of the first process gas between the first setting time and the second setting time.

18. The method of claim 11, wherein the intrinsic layer includes a first region having a non-uniform concentration of germanium.

19. The method of claim 18, wherein the first region of the intrinsic layer contacts the seed layer.

20. The method of claim 18, wherein the intrinsic layer further includes a second region having a uniform concentration of germanium.
